(19) United States
(12) Patent Application Publication
(10) Pub. No.: US 2025/0223723 A1
(43) Pub. Date: Jul. 10, 2025

(54) SILICON CARBIDE SEED, SILICON CARBIDE CRYSTAL AND METHOD OF FABRICATING THE SAME

(71) Applicant: GlobalWafers Co., Ltd., Hsinchu (TW)

(72) Inventor: Ching-Shan Lin, Hsinchu (TW)

(73) Assignee: GlobalWafers Co., Ltd., Hsinchu (TW)

(21) Appl. No.: 19/008,634

(22) Filed: Jan. 3, 2025

Related U.S. Application Data
(60) Provisional application No. 63/619,316, filed on Jan. 10, 2024.

(51) Int. Cl. C30B 29/36; C30B 28/02; C30B 28/14

(52) U.S. Cl. CPC C30B 29/36; C30B 28/02; C30B 28/14

(57) ABSTRACT

A silicon carbide seed is provided, including a first seed layer and a second seed layer. The first seed layer includes a polycrystalline silicon carbide material. The second seed layer is directly attached to the first seed layer, where the second seed layer includes a single crystal silicon carbide material, and a thickness ratio (T2/T1) of a thickness T1 of the first seed layer to a thickness T2 of the second seed layer is in a range of 10% to 50%.

### CROSS-REFERENCE TO RELATED APPLICATION

This application claims the priority benefit of U.S. provisional application Ser. No. 63/619,316, filed on Jan. 10, 2024. The entirety of the above-mentioned patent application is hereby incorporated by reference herein and made a part of this specification.

### BACKGROUND

### Technical Field

The disclosure relates to a silicon carbide seed, and particularly relates to a silicon carbide crystal and a method of using the silicon carbide seed to fabricate the silicon carbide crystal.

### Description of Related Art

Silicon carbide (SiC) is a wide-band-gap semiconductor material. Silicon carbide has many remarkable physical properties, making it a major component in today's high-power, high-temperature and high frequency electronics.

Silicon carbide crystals are generally grown using 6H silicon carbide or 4H silicon carbide as seeds. Among the costs of growing silicon carbide crystals, the cost of seeds occupies a large part. Therefore, if the cost of seeds may be reduced and the quality of grown crystals may be improved at the same time, the competitiveness of products will be greatly improved.

### SUMMARY

The disclosure provides a silicon carbide seed, which has a reusable seed layer, and the silicon carbide crystal obtained by using the seed to perform a crystal growth process has better quality.

A silicon carbide seed of the disclosure includes a first seed layer and a second seed layer. The first seed layer includes a polycrystalline silicon carbide material. The second seed layer is directly attached to the first seed layer, where the second seed layer includes a single crystal silicon carbide material, and a thickness ratio (T2/T1) of a thickness T1 of the first seed layer to a thickness T2 of the second seed layer is in a range of 10% to 50%.

In some embodiments, the thickness ratio (T2/T1) is in a range of 30% to 50%.

In some embodiments, the polycrystalline silicon carbide material forming the first seed layer is formed by a physical vapor transport process in a temperature range of 1900° C. to 2300° C., and a grain size of the formed polycrystalline silicon carbide material is in a range of 1 mm to 20 mm.

In some embodiments, the polycrystalline silicon carbide material forming the first seed layer is formed by a powder hot pressing process in a temperature range of 1800° C. to 2100° C., and a grain size of the formed polycrystalline silicon carbide material is in a range of 1 μm to 500 μm.

In some embodiments, the polycrystalline silicon carbide material forming the first seed layer is formed by a chemical vapor deposition process in a temperature range of 1200° C. to 1600° C., and a grain size of the formed polycrystalline silicon carbide material is in a range of 5 μm to 50 μm.

In some embodiments, the second seed layer has a basal plane dislocation (BPD) density of less than 500 ea/cm², a threading screw dislocation (TSD) density of less than 30 ea/cm², and a bar stacking fault (BSF) density of less than 30 ea/wafer.

In some embodiments, the thickness T1 of the first seed layer is 2000 μm or less, and the thickness T2 of the second seed layer is 1000 μm or less.

The method of fabricating a silicon carbide crystal of the disclosure includes the following steps. A silicon carbide seed is formed, where forming the silicon carbide seed includes: forming a first seed layer, where the first seed layer includes a polycrystalline silicon carbide material; forming a second seed layer, where the second seed layer includes a single crystal silicon carbide material, and a thickness ratio (T2/T1) of a thickness T1 of the first seed layer to a thickness T2 of the second seed layer is in a range of 10% to 50%; and directly attaching the second seed layer to the first seed layer to form the silicon carbide seed. A raw material containing a carbon element and a silicon element is provided in a reactor, and the silicon carbide seed is disposed above the raw material. A silicon carbide crystal growth process is performed using the second seed layer of the silicon carbide seed as a crystal growth surface. The growth process includes heating the reactor and the raw material to fabricate the silicon carbide crystal on the silicon carbide seed.

In some embodiments, after the silicon carbide crystal is fabricated, the method further includes peeling off the second seed layer from the silicon carbide seed, and reusing the first seed layer to perform a growth process of another silicon carbide crystal.

In some embodiments, the polycrystalline silicon carbide material forming the first seed layer is formed by a physical vapor transport process in a temperature range of 1900° C. to 2300° C., and a thermal conductivity of the polycrystalline silicon carbide material formed by the physical vapor transport process is 180 w/mK or more.

In some embodiments, the polycrystalline silicon carbide material forming the first seed layer is formed by a powder hot pressing process in a temperature range of 1800° C. to 2100° C., and a thermal conductivity of the polycrystalline silicon carbide material formed by the powder hot pressing process is 100 w/mK or more.

In some embodiments, the polycrystalline silicon carbide material forming the first seed layer is formed by a chemical vapor deposition process in a temperature range of 1200° C. to 1600° C., and a thermal conductivity of the polycrystalline silicon carbide material formed by the chemical vapor deposition process is 150 w/mK or more.

The silicon carbide crystal of the disclosure may be fabricated by the above method of fabricating the silicon carbide crystal, where the silicon carbide crystal has a basal plane dislocation (BPD) density of less than 500 ea/cm², a threading screw dislocation (TSD) density of less than 20 ea/cm², and a bar stacking fault (BSF) density of less than 10 ea/wafer.

Based on the above, embodiments of the disclosure use the first seed layer including the polycrystalline silicon carbide material and the second seed layer including single crystal silicon carbide material as the silicon carbide seed, and control the relative thickness of the first seed layer and the second seed layer. Accordingly, the silicon carbide crystal formed by the silicon carbide seed may have good geometric quality.

### BRIEF DESCRIPTION OF THE DRAWINGS

FIG. 1 is a schematic diagram of a composition of a silicon carbide seed according to some embodiments of the disclosure.

FIG. 2 is a schematic diagram of a crystal growth equipment according to an embodiment of the disclosure.

FIG. 3 is a flow chart of a method of fabricating a silicon carbide crystal according to an embodiment of the disclosure.

### DESCRIPTION OF THE EMBODIMENTS

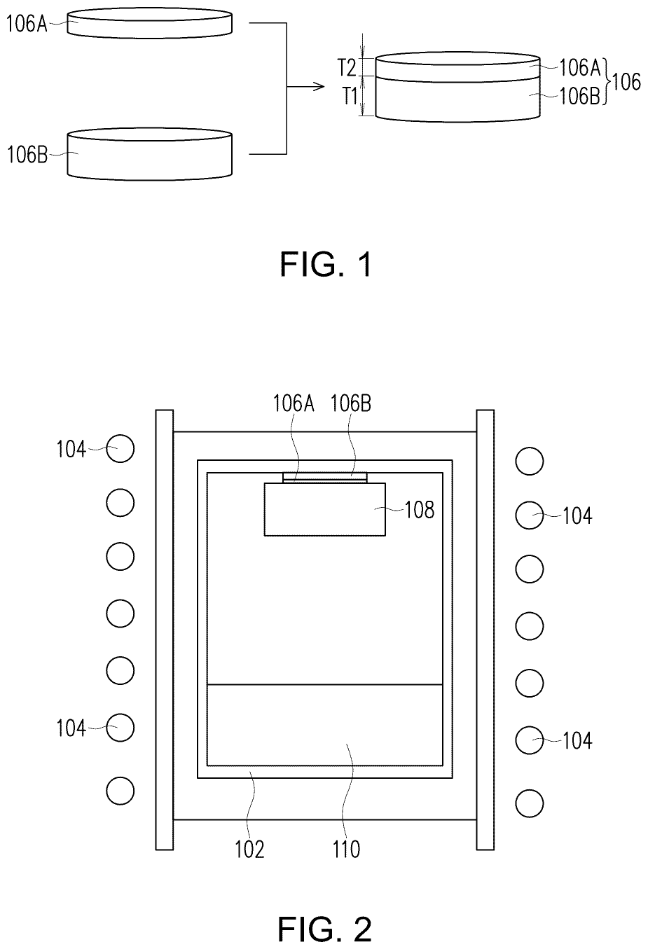

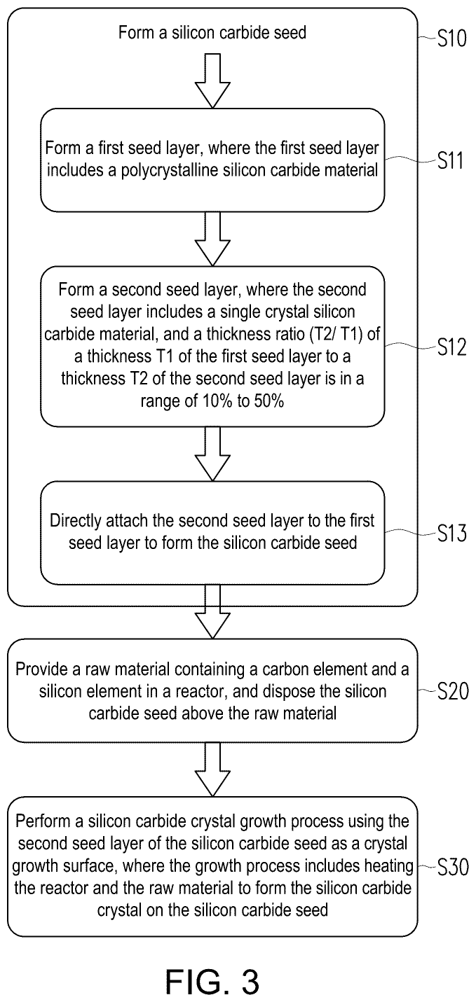

FIG. 1 is a schematic diagram of a composition of a silicon carbide seed according to some embodiments of the disclosure. FIG. 2 is a schematic diagram of a crystal growth equipment according to an embodiment of the disclosure. FIG. 3 is a flow chart of a method of fabricating a silicon carbide crystal according to an embodiment of the disclosure. Hereinafter, the method of fabricating the silicon carbide crystal in some embodiments of the disclosure will be described with reference to the silicon carbide seed depicted in FIG. 1 and the crystal growth equipment depicted in FIG. 2 in conjunction with the flow chart depicted in FIG. 3.

As shown in step S10 of FIG. 1 and FIG. 3, in the method of fabricating the silicon carbide crystal according to the embodiment of the disclosure, a silicon carbide seed 106 is formed in advance. In some embodiments, the method of forming the silicon carbide seed 106 includes performing step S11 of FIG. 3 to form a first seed layer 106B, where the first seed layer 106B includes a polycrystalline silicon carbide material.

In some embodiments, the polycrystalline silicon carbide material of the first seed layer 106B is formed by a physical vapor transport (PVT) process in a temperature range of 1900° C. to 2300° C. through a process A, and the thermal conductivity of the polycrystalline silicon carbide material formed by the physical vapor transport process is 180 w/mK or more. In addition, the grain size of the formed polycrystalline silicon carbide material is in a range of 1 mm to 20 mm.

In another embodiment, the polycrystalline silicon carbide material of the first seed layer 106B is formed by a powder hot pressing process in a temperature range of 1800° C. to 2100° C. through a process B, and the thermal conductivity of the polycrystalline silicon carbide material formed by the powder hot pressing process is 100 w/mK or more. In addition, the grain size of the formed polycrystalline silicon carbide material is in a range of 1 μm to 500 μm.

In yet another embodiment, the polycrystalline silicon carbide material of the first seed layer 106B is formed by a chemical vapor deposition process in a temperature range of 1200° C. to 1600° C. through a process C, and the thermal conductivity of the polycrystalline silicon carbide material formed by the chemical vapor deposition process is 150 w/mK or more. In addition, the grain size of the formed polycrystalline silicon carbide material is in a range of 5 μm to 50 μm.

After forming the first seed layer 106B, step S12 of FIG. 3 is then performed to form a second seed layer 106A. The second seed layer 106A includes a single crystal silicon carbide material, and the second seed layer 106A has a basal plane dislocation (BPD) density of less than 500 ea/cm², a threading screw dislocation (TSD) density of less than 30 ea/cm², and a bar stacking fault (BSF) density of less than 30 ea/wafer.

In some embodiments, a thickness ratio (T2/T1) of a thickness T1 of the first seed layer 106B to a thickness T2 of the second seed layer 106A is controlled in a range of 10% to 50%. In some embodiments, the thickness ratio (T2/T1) is controlled in a range of 30% to 50%. In other words, the first seed layer 106B is a relatively thick seed layer, and the second seed layer 106A is a relatively thin seed layer. In an exemplary embodiment, when the thickness ratio (T2/T1) of the first seed layer 106B and the second seed layer 106A in the silicon carbide seed 106 is controlled within the above range, the formed silicon carbide crystal may have better geometric quality.

In addition, when the above thickness ratio is met, the thickness T1 of the first seed layer 106B is, for example, 2000 μm or less, and the thickness T2 of the second seed layer 106A is, for example, 1000 μm or less. In some embodiments, the total thickness of the first seed layer 106B and the second seed layer 106A is, for example, 3000 μm or less.

After the second seed layer 106A is formed, step S13 of FIG. 3 is performed to directly attach the second seed layer 106A to the first seed layer 106B to form the silicon carbide seed 106. In the embodiment of the disclosure, the second seed layer 106A is attached in direct contact with the surface of the first seed layer 106B. In other words, there is no intermediary material between the first seed layer 106B and the second seed layer 106A. In some embodiments, the method of attaching the second seed layer 106A include using ion implantation, reactive ion etching plasma (RIE plasma), epitaxy, chemical vapor deposition (CVD), surface activation, laser, or a combination thereof to attach to the first seed layer 106B.

Next, referring to FIG. 2 and step S20 of FIG. 3, a raw material 110 containing a carbon element and a silicon element and the silicon carbide seed 106 (including the first seed layer 106B and the second seed layer 106A) located above the raw material 110 are provided within a reactor 102. For example, the raw material 110 is silicon carbide powder, which is disposed at the bottom of the reactor 102 as a solid sublimation source. The silicon carbide seed 106 is disposed at the top of the reactor 102. In some embodiments, the silicon carbide seed 106 may be fixed on the seed carrying platform (not shown) through an adhesive layer, or may be fixed on the seed carrying platform using other fixtures, and the disclosure is not limited thereto. In some embodiments, the second seed layer 106A of the silicon carbide seed 106 is a crystal growth surface. Therefore, the silicon carbide seed 106 is fixed on the seed carrying platform (not shown) through the first seed layer 106B.

Next, as shown in FIG. 2 and step S30 of FIG. 3, a silicon carbide crystal growth process is performed to form a silicon carbide crystal 108 as shown in FIG. 2. For example, the growth process of the silicon carbide crystal 108 is performed using the second seed layer 106A of the silicon carbide seed 106 as a crystal growth surface. The growth process includes heating the reactor 102 and the raw material 100 to fabricate the silicon carbide crystal 108 on the silicon carbide seed 106.

In the above step S30, the silicon carbide crystal 108 is fabricated on the silicon carbide seed 106 by a physical vapor transport (PVT) method. In some embodiments, the reactor 102 and the raw material 110 are heated by an inductive coil 104 to fabricate the silicon carbide crystal 108 on the silicon carbide seed 106. During the process, the silicon carbide seed 106 receives the raw material 110 (silicon carbide powder) solidified from the gaseous state, and slowly grows semiconductor crystals on the silicon carbide seed 106 until the silicon carbide crystal 108 with a desired size is obtained. After the silicon carbide crystal 108 is grown to the desired size, the reactor 102 and the raw material 110 are cooled to obtain a silicon carbide ingot composed of the silicon carbide crystal 108. In some embodiments, the formed ingot may have different crystal structures depending on the single crystal seed orientation used in the second seed layer 106A. For example, the silicon carbide ingot includes 4H-silicon carbide, 6H-silicon carbide, etc. Both 4H-silicon carbide and 6H-silicon carbide belong to the hexagonal crystal system; in addition, the method of fabricating the seed 106 and the silicon carbide crystal 108 may both use physical vapor transport (PVT), but different growth methods may also be adopted, and the disclosure is not limited thereto.

In the embodiment of the disclosure, when the silicon carbide crystal 108 is formed by using the silicon carbide seed 106 having the first seed layer 106B and the second seed layer 106A, the fabricated silicon carbide crystal 108 may have better geometric quality. For example, the basal plane dislocation (BPD) density of the obtained silicon carbide crystal 108 may be controlled to be less than 500 ea/cm², the threading screw dislocation (TSD) density may be controlled to be less than 20 ea/cm², and the bar stacking fault (BSF) density may be controlled to be less than 10 ea/wafer. After the silicon carbide crystal 108 is fabricated, the second seed layer 106A may be peeled off from the silicon carbide seed 106, and the first seed layer 106B may be reused to perform a growth process of another silicon carbide crystal 108.

### Embodiments

In order to prove that the silicon carbide crystal 108 fabricated using the silicon carbide seed 106 of the disclosure has better quality, the following embodiments are particularly used to illustrate.

In the embodiment, the steps are as shown in FIG. 1 to FIG. 3 above, and various conditions of the first seed layer and the second seed layer are controlled as described in Table 1 to Table 3 below to fabricate the silicon carbide crystal. In the embodiment shown in Table 1, the first seed layer was formed by a physical vapor transport method (process A). In the embodiment shown in Table 2, the first seed layer was formed by a powder hot pressing process (process B). In the embodiment shown in Table 3, the first seed layer was formed by a chemical vapor deposition process (process C). The results of the fabricated silicon carbide crystals are shown in Table 1 to Table 3 below.

TABLE 1

| | | Con- | Con- | Con- | Con- | Con- | | | | | | | | |
|---|---|---|---|---|---|---|---|---|---|---|---|---|---|---|
| | | trol | trol | trol | trol | trol | Embo- | Embo- | Embo- | Embo- | Embo- | Embo- | Embo- | Embo- |
| | | Group | Group | Group | Group | Group | diment | diment | diment | diment | diment | diment | diment | diment |
| Process A | | A1 | A2 | A3 | A4 | A5 | A1 | A2 | A3 | A4 | A5 | A6 | A7 | A8 |
| First | Process | 2350 | 2380 | 2400 | 2320 | 2450 | 2100 | 2150 | 2300 | 2200 | 2080 | 1900 | 1980 | 2010 |
| seed | temper- | | | | | | | | | | | | | |
| layer | ature (° C.) | | | | | | | | | | | | | |
| (Poly- | Thermal | 60 | 150 | 138 | 142 | 155 | 185 | 210 | 198 | 225 | 250 | 265 | 245 | 235 |
| crystal- | conduc- | | | | | | | | | | | | | |
| line) | tivity | | | | | | | | | | | | | |
| | (w/mK) | | | | | | | | | | | | | |
| | Grain | 25 | 35 | 18 | 16 | 12 | 14 | 16 | 15 | 19 | 8 | 1 | 20 | 12 |
| | size (mm) | | | | | | | | | | | | | |
| | Thickness | 280 | 800 | 550 | 630 | 1200 | 250 | 350 | 430 | 580 | 1550 | 1990 | 540 | 230 |
| | T1 (μm) | | | | | | | | | | | | | |
| Second | BPD | 488 | 432 | 375 | 251 | 782 | 480 | 353 | 302 | 252 | 158 | 45 | 67 | 75 |
| seed layer | (ea/cm²) | | | | | | | | | | | | | |
| (Single | TSD | 25 | 22 | 29 | 26 | 67 | 28 | 22 | 20 | 19 | 15 | 11 | 16 | 22 |
| crystal) | (ea/cm²) | | | | | | | | | | | | | |
| | BSF | 19 | 22 | 17 | 18 | 45 | 25 | 18 | 15 | 10 | 8 | 5 | 15 | 23 |
| | (ea/wafer) | | | | | | | | | | | | | |
| | Thickness | 168 | 280 | 50 | 32 | 300 | 25 | 88 | 151 | 220 | 698 | 995 | 259 | 115 |
| | T2 (μm) | | | | | | | | | | | | | |

| | | | | | | | | | | | | | |
|---|---|---|---|---|---|---|---|---|---|---|---|---|---|
| Thickness ratio (T2/T1) | 60% | 35% | 9% | 5% | 25% | 10% | 25% | 35% | 38% | 45% | 50% | 48% | 50% |

Analysis of silicon carbide crystal quality

| | | | | | | | | | | | | | |
|---|---|---|---|---|---|---|---|---|---|---|---|---|---|
| Crystal BPD (ea/cm²) | 755 | 658 | 652 | 680 | 756 | 450 | 303 | 250 | 212 | 138 | 25 | 89 | 102 |
| Crystal TSD(ea/cm²) | 120 | 32 | 112 | 132 | 68 | 20 | 19 | 18 | 16 | 14 | 5 | 8 | 11 |
| Crystal BSF (ea/wafer) | 18 | 23 | 17 | 19 | 48 | 10 | 8 | 8 | 6 | 5 | 4 | 3 | 2 |
| Evaluation | NG | NG | NG | NG | NG | G | G | G | G | G | G | G | G |

TABLE 2

| | | Con- | Con- | Con- | Con- | Con- | | | | | | | | |
|---|---|---|---|---|---|---|---|---|---|---|---|---|---|---|
| | | trol | trol | trol | trol | trol | Embo- | Embo- | Embo- | Embo- | Embo- | Embo- | Embo- | Embo- |
| | | Group | Group | Group | Group | Group | diment | diment | diment | diment | diment | diment | diment | diment |
| Process B | | B1 | B2 | B3 | B4 | B5 | B1 | B2 | B3 | B4 | B5 | B6 | B7 | B8 |
| First | Process | 2000 | 2150 | 1990 | 1890 | 2100 | 1880 | 1980 | 1900 | 2000 | 1830 | 2080 | 1850 | 1800 |
| seed | temper- | | | | | | | | | | | | | |
| layer | ature (° C.) | | | | | | | | | | | | | |
| (Poly- | Thermal | 95 | 90 | 80 | 78 | 85 | 120 | 145 | 255 | 285 | 310 | 270 | 480 | 505 |
| crystal- | conduc- | | | | | | | | | | | | | |
| line) | tivity | | | | | | | | | | | | | |
| | (w/mK) | | | | | | | | | | | | | |
| | Grain | 580 | 660 | 353 | 35 | 120 | 32 | 277 | 153 | 380 | 9 | 492 | 21 | 3 |
| | size (μm) | | | | | | | | | | | | | |
| | Thickness | 320 | 750 | 553 | 610 | 350 | 290 | 360 | 420 | 1400 | 1800 | 540 | 200 | 232 |
| | T1 (μm) | | | | | | | | | | | | | |
| Second | BPD | 483 | 335 | 412 | 243 | 656 | 82 | 353 | 324 | 471 | 158 | 492 | 72 | 78 |
| seed | (ea/cm²) | | | | | | | | | | | | | |
| layer | TSD | 24 | 25 | 29 | 25 | 54 | 11 | 22 | 21 | 27 | 15 | 30 | 8 | 21 |
| (Single | (ea/cm²) | | | | | | | | | | | | | |
| crystal) | BSF | 18 | 21 | 18 | 16 | 35 | 5 | 18 | 16 | 26 | 8 | 29 | 5 | 20 |
| | (ea/wafer) | | | | | | | | | | | | | |
| | Thickness | 176 | 173 | 44 | 31 | 42 | 145 | 90 | 160 | 29 | 644 | 259 | 100 | 35 |
| | T2 (μm) | | | | | | | | | | | | | |

| | | | | | | | | | | | | | |
|---|---|---|---|---|---|---|---|---|---|---|---|---|---|
| Thickness ratio (T2/T1) | 55% | 23% | 8% | 5% | 12% | 50% | 25% | 38% | 10% | 46% | 48% | 50% | 15% |

Analysis of silicon carbide crystal quality

| | | | | | | | | | | | | | |
|---|---|---|---|---|---|---|---|---|---|---|---|---|---|
| Crystal BPD (ea/cm²) | 765 | 653 | 580 | 553 | 756 | 30 | 360 | 335 | 475 | 25 | 498 | 62 | 102 |
| Crystal TSD(ea/cm²) | 132 | 45 | 102 | 101 | 62 | 11 | 18 | 17 | 19 | 8 | 20 | 5 | 11 |
| Crystal BSF (ea/wafer) | 19 | 28 | 16 | 12 | 42 | 2 | 5 | 8 | 13 | 2 | 14 | 2 | 5 |
| Evaluation | NG | NG | NG | NG | NG | G | G | G | G | G | G | G | G |

TABLE 3

| | | Con- | Con- | Con- | Con- | Con- | Cont- | | | | | | | | |
|---|---|---|---|---|---|---|---|---|---|---|---|---|---|---|---|
| | | trol | trol | trol | trol | trol | rol | Embo- | Embo- | Embo- | Embo- | Embo- | Embo- | Embo- | Embo- |
| | | Group | Group | Group | Group | Group | Group | diment | diment | diment | diment | diment | diment | diment | diment |
| Process C | | C1 | C2 | C3 | C4 | C5 | C6 | C1 | C2 | C3 | C4 | C5 | C6 | C7 | C8 |
| First | Process | 1650 | 1720 | 1700 | 1770 | 1680 | 1720 | 1600 | 1550 | 1500 | 1560 | 1400 | 1200 | 1350 | 1300 |
| seed | temper- | | | | | | | | | | | | | | |
| layer | ature (° C.) | | | | | | | | | | | | | | |
| (Poly- | Thermal | 112 | 140 | 130 | 132 | 90 | 95 | 152 | 182 | 250 | 652 | 192 | 182 | 175 | 458 |
| crystal- | conduc- | | | | | | | | | | | | | | |
| line) | tivity | | | | | | | | | | | | | | |
| | (w/mK) | | | | | | | | | | | | | | |
| | Grain | 80 | 3 | 65 | 18 | 16 | 95 | 45 | 20 | 15 | 35 | 12 | 1 | 8 | 5 |
| | size (μm) | | | | | | | | | | | | | | |
| | Thickness | 280 | 150 | 1200 | 550 | 630 | 1500 | 260 | 330 | 400 | 550 | 1650 | 1990 | 180 | 220 |
| | T1 (μm) | | | | | | | | | | | | | | |
| Second | BPD | 488 | 55 | 656 | 375 | 251 | 352 | 465 | 334 | 298 | 245 | 301 | 35 | 79 | 98 |
| seed | (ea/cm²) | | | | | | | | | | | | | | |
| layer | TSD | 25 | 18 | 43 | 29 | 26 | 15 | 30 | 25 | 23 | 21 | 27 | 10 | 14 | 18 |
| (Single | (ea/cm²) | | | | | | | | | | | | | | |
| crystal) | BSF | 19 | 16 | 41 | 17 | 18 | 14 | 25 | 18 | 15 | 10 | 17 | 6 | 8 | 9 |
| | (ea/wafer) | | | | | | | | | | | | | | |
| | Thickness | 168 | 120 | 456 | 50 | 32 | 975 | 26 | 83 | 140 | 209 | 743 | 995 | 86 | 110 |
| | T2 (μm) | | | | | | | | | | | | | | |

| | | | | | | | | | | | | | | |
|---|---|---|---|---|---|---|---|---|---|---|---|---|---|---|
| Thickness ratio (T2/T1) | 60% | 80% | 38% | 9% | 5% | 65% | 10% | 25% | 35% | 38% | 45% | 50% | 48% | 50% |

Analysis of silicon carbide crystal quality

| | | | | | | | | | | | | | | |
|---|---|---|---|---|---|---|---|---|---|---|---|---|---|---|
| Crystal BPD (ea/cm²) | 755 | 560 | 756 | 652 | 680 | 568 | 450 | 301 | 250 | 212 | 298 | 32 | 46 | 15 |
| Crystal TSD(ea/cm²) | 120 | 22 | 58 | 112 | 132 | 35 | 19 | 19 | 18 | 16 | 18 | 11 | 8 | 5 |
| Crystal BSF (ea/wafer) | 18 | 12 | 51 | 17 | 19 | 25 | 10 | 8 | 8 | 6 | 8 | 4 | 3 | 2 |
| Evaluation | NG | NG | NG | NG | NG | NG | G | G | G | G | G | G | G | G |

Referring to the experimental results in Table 1, as shown in Embodiment A1 to Embodiment A8, when the thickness ratio (T2/T1) of the thickness T1 of the first seed layer to the thickness T2 of the second seed layer is in a range of 10% to 50%, and the process conditions of the first seed layer (i.e. the process conditions of the physical vapor transport method) and the conditions of the second seed layer are within a predetermined range, the obtained silicon carbide crystal may have better geometric quality (evaluation G). That is, the basal plane dislocation (BPD) density, threading screw dislocation (TSD) density, and bar stacking fault (BSF) density of the obtained silicon carbide crystal may be controlled to be less than 500 ea/cm², be less than 20 ea/cm², and be less than 10 ea/wafer.

In comparison, with reference to Control Group A1, Control Group A3, and Control Group A4, if the thickness ratio (T2/T1) of the thickness T1 of the first seed layer to the thickness T2 of the second seed layer is outside the range of 10% to 50%, the basal plane dislocation (BPD) density, threading screw dislocation (TSD) density, and bar stacking fault (BSF) density of the obtained silicon carbide crystal are all poor (evaluation NG). Referring to Control Group A2, even if the thickness ratio (T2/T1) is in the range of 10% to 50%, if the grain size of the first seed layer formed by physical vapor transport method is not in the range of 1 mm to 20 mm, then the basal plane dislocation (BPD) density, threading screw dislocation (TSD) density, and bar stacking fault (BSF) density of the obtained silicon carbide crystal are also poor (evaluation NG). In addition, referring to Control Group A5, even if the thickness ratio (T2/T1) is in the range of 10% to 50%, if the basal plane dislocation (BPD) density, threading screw dislocation (TSD) density, and bar stacking fault (BSF) density of the second seed layer are not controlled to be less than 500 ea/cm², be less than 30 ea/cm², and be less than 30 ea/wafer, then the basal plane dislocation (BPD) density, threading screw dislocation (TSD) density, and bar stacking fault (BSF) density of the obtained silicon carbide crystal are also poor (evaluation NG).

Referring to the experimental results in Table 2, as shown in Embodiment B1 to Embodiment B8, when the thickness ratio (T2/T1) of the thickness T1 of the first seed layer to the thickness T2 of the second seed layer is in the range of 10% to 50%, and the process conditions of the first seed layer (i.e. the process conditions of the powder hot pressing process) and the conditions of the second seed layer are within a predetermined range, the obtained silicon carbide crystal may have better geometric quality (evaluation G). That is, the basal plane dislocation (BPD) density, threading screw dislocation (TSD) density, and bar stacking fault (BSF) density of the obtained silicon carbide crystal may be controlled to be less than 500 ea/cm², be less than 20 ea/cm², and be less than 10 ea/wafer.

In comparison, with reference to Control Group B1, Control Group B3, and Control Group B4, if the thickness ratio (T2/T1) of the thickness T1 of the first seed layer to the thickness T2 of the second seed layer is outside the range of 10% to 50%, the basal plane dislocation (BPD) density, threading screw dislocation (TSD) density, and bar stacking fault (BSF) density of the obtained silicon carbide crystal are all poor (evaluation NG). Referring to Control Group B2, even if the thickness ratio (T2/T1) is in the range of 10% to 50%, if the grain size of the first seed layer formed by the powder hot pressing process is not in the range of 1 μm to 500 μm, then the basal plane dislocation (BPD) density, threading screw dislocation (TSD) density, and bar stacking fault (BSF) density of the obtained silicon carbide crystal are also poor (evaluation NG). in addition, refer to Control Group B5, even if the thickness ratio (T2/T1) is in the range of 10% to 50%, if the basal plane dislocation (BPD) density, threading screw dislocation (TSD) density, and bar stacking fault (BSF) density of the second seed layer is not controlled to be less than 500 ea/cm², be less than 30 ea/cm², and be less than 30 ea/wafer, then the basal plane dislocation (BPD) density, threading screw dislocation (TSD) density, and bar stacking fault (BSF) density of the obtained silicon carbide crystal are also poor (evaluation NG).

Referring to the experimental results in Table 3, as shown in Embodiment C1 to Embodiment C8, when the thickness ratio (T2/T1) of the thickness T1 of the first seed layer to the thickness T2 of the second seed layer is in the range of 10% to 50%, and the process conditions of the first seed layer (i.e. the process conditions of the chemical vapor deposition process) and the conditions of the second seed layer are within a predetermined range, the obtained silicon carbide crystal may have better geometric quality (evaluation G). That is, the basal plane dislocation (BPD) density, threading screw dislocation (TSD) density, and bar stacking fault (BSF) density of the obtained silicon carbide crystal may be controlled to be less than 500 ea/cm², be less than 20 ea/cm², and be less than 10 ea/wafer.

In comparison, with reference to the Control Group C1 to C2 and the Control Group C4 to C6, if the thickness ratio (T2/T1) of the thickness T1 of the first seed layer to the thickness T2 of the second seed layer is outside the range of 10% to 50%, the basal plane dislocation (BPD) density, threading screw dislocation (TSD) density, and bar stacking fault (BSF) density of the obtained silicon carbide crystal are all poor (evaluation NG). Referring to Control Group C3, even if the thickness ratio (T2/T1) is in the range of 10% to 50%, if the grain size of the first seed layer formed by the chemical vapor deposition process is not in the range of 5 μm to 50 μm, and the basal plane dislocation (BPD) density, threading screw dislocation (TSD) density, and bar stacking fault (BSF) density of the second seed layer is not controlled to be less than 500 ea/cm², be less than 30 ea/cm², and be less than 30 ea/wafer, then the basal plane dislocation (BPD) density, threading screw dislocation (TSD) density, and bar stacking fault (BSF) density of the obtained silicon carbide crystal are also poor (evaluation NG).

To sum up, in the embodiments of the disclosure, the first seed layer including the polycrystalline silicon carbide material and the second seed layer including the single crystal silicon carbide material are used as the silicon carbide seed, and the relative thickness of the first seed layer and the second seed layer is controlled. Accordingly, the silicon carbide crystal formed by the silicon carbide seed may have good geometric quality. In addition, since the first seed layer in the silicon carbide seed may be reused, the quality of the grown crystal may be improved while the cost of the seed may be reduced, thereby greatly improving the competitiveness of the product.

What is claimed is:

1. A silicon carbide seed, comprising:
a first seed layer, wherein the first seed layer comprises a polycrystalline silicon carbide material;
a second seed layer, directly attached to the first seed layer, wherein the second seed layer comprises a single crystal silicon carbide material, and a thickness ratio (T2/T1) of a thickness T1 of the first seed layer to a thickness T2 of the second seed layer (T2/T1) is in a range of 10% to 50%.

2. The silicon carbide seed according to claim 1, wherein the thickness ratio (T2/T1) is in a range of 30% to 50%.

3. The silicon carbide seed according to claim 1, wherein the polycrystalline silicon carbide material of the first seed layer is formed by a physical vapor transport process in a temperature range of 1900° C. to 2300° C., and a grain size of the formed polycrystalline silicon carbide material is in a range of 1 mm to 20 mm.

4. The silicon carbide seed according to claim 1, wherein the polycrystalline silicon carbide material of the first seed layer is formed by a powder hot pressing process in a temperature range of 1800° C. to 2100° C., and a grain size of the formed polycrystalline silicon carbide material is in a range of 1 μm to 500 μm.

5. The silicon carbide seed according to claim 1, wherein the polycrystalline silicon carbide material of the first seed layer is formed by a chemical vapor deposition process in a temperature range of 1200° C. to 1600° C., and a grain size of the formed polycrystalline silicon carbide material is in a range of 5 μm to 50 μm.

6. The silicon carbide seed according to claim 1, wherein the second seed layer has a basal plane dislocation (BPD) density of less than 500 ea/cm², a threading screw dislocation (TSD) density of less than 30 ea/cm², and a bar stacking fault (BSF) density of less than 30 ea/wafer.

7. The silicon carbide seed according to claim 1, wherein the thickness T1 of the first seed layer is 2000 μm or less, and the thickness T2 of the second seed layer is 1000 μm or less.

8. A method of fabricating a silicon carbide crystal, comprising:
forming a silicon carbide seed, wherein forming the silicon carbide seed comprises:
forming a first seed layer, wherein the first seed layer comprises a polycrystalline silicon carbide material;
forming a second seed layer, wherein the second seed layer comprises a single crystal silicon carbide material, and a thickness ratio (T2/T1) of a thickness T1 of the first seed layer to a thickness T2 of the second seed layer is in a range of 10% to 50%; and
directly attaching the second seed layer to the first seed layer to form the silicon carbide seed;
providing a raw material containing a carbon element and a silicon element in a reactor, and disposing the silicon carbide seed above the raw material; and
performing a silicon carbide crystal growth process using the second seed layer of the silicon carbide seed as a crystal growth surface, wherein the growth process comprises heating the reactor and the raw material to form the silicon carbide crystal on the silicon carbide seed.

9. The method according to claim 8, wherein after forming the silicon carbide crystal, further comprising peeling off the second seed layer from the silicon carbide seed and reusing the first seed layer to perform another silicon carbide crystal growth process.

10. The method according to claim 8, wherein the polycrystalline silicon carbide material forming the first seed layer is formed by a physical vapor transport process in a temperature range of 1900° C. to 2300° C., and a thermal conductivity of the polycrystalline silicon carbide material formed by the physical vapor transport process is 180 w/mK or more.

11. The method according to claim 8, wherein the polycrystalline silicon carbide material forming the first seed layer is formed by a powder hot pressing process in a temperature range of 1800° C. to 2100° C., and a thermal conductivity of the polycrystalline silicon carbide material formed by the powder hot pressing process is 100 w/mK or more.

12. The method according to claim 8, wherein the polycrystalline silicon carbide material forming the first seed layer is formed by a chemical vapor deposition process in a temperature range of 1200° C. to 1600° C., and a thermal conductivity of the polycrystalline silicon carbide material formed by the chemical vapor deposition process is 150 w/mK or more.

13. The silicon carbide crystal fabricated by the method according to claim 8, wherein the silicon carbide crystal has a basal plane dislocation (BPD) density of less than 500 ea/cm², a threading screw dislocation (TSD) density of less than 20 ea/cm², and a bar stacking fault (BSF) density of 10 ea/wafer.
